(19) United States
(12) Patent Application Publication
(10) Pub. No.: US 2024/0072184 A1
(43) Pub. Date: Feb. 29, 2024

(54) PHOTODETECTORS ON FIN STRUCTURE

(71) Applicant: GlobalFoundries U.S. Inc., Malta, NY (US)

(72) Inventors: Ramsey HAZBUN, Colchester, VT (US); John ELLIS-MONAGHAN, Grand Isle, VT (US); Siva P. ADUSUMILLI, South Burlington, VT (US); Rajendran KRISHNASAMY, Essex Junction, VT (US)

(21) Appl. No.: 17/895,599

(22) Filed: Aug. 25, 2022

(51) Int. Cl. H01L 31/0352; H01L 31/18

(52) U.S. Cl. CPC H01L 31/035281; H01L 31/18; H01L 31/028

(57) ABSTRACT

The present disclosure relates to semiconductor structures and, more particularly, to photodetectors and methods of manufacture. The structure includes: a trench structure in a semiconductor substrate; at least one fin structure comprising semiconductor material which extends from a bottom of the trench structure; a photodetector material within the trench structure and extends from the at least one fin structure; a first contact connected to and on a first side of the photodetector material; and a second contact connected to the semiconductor substrate on a second side of the photodetector material.

### BACKGROUND

The present disclosure relates to semiconductor structures and, more particularly, to photodetectors and methods of manufacture.

Photodetectors are devices which precisely convert light into electrical signals, and are used, for example, in many different types of imaging, sensing and communication applications. To this end, photodetectors are generally formed using light sensitive material, such as Ge, which are excellent light absorbers. However, Ge photodetectors may exhibit a high dislocation density which impinges on device performance. For example, during the fabrication process, Ge material may exhibit defects due to a lattice mismatch between the Ge material and the underlying substrate material, e.g., Si. The defects result in leakage pathways which, in turn, may drive an increase in dark current. The defects will also result in a poor signal to noise ratio. Accordingly, the lattice mismatch may lead to problems both in terms of accuracy and efficiency for the devices.

### SUMMARY

In an aspect of the disclosure, a structure comprises: a trench structure in a semiconductor substrate; at least one fin structure comprising semiconductor material which extends from a bottom of the trench structure; a photodetector material within the trench structure and extends from the at least one fin structure; a first contact connected to and on a first side of the photodetector material; and a second contact connected to the semiconductor substrate on a second side of the photodetector material.

In an aspect of the disclosure, a structure comprises: a trench structure in a semiconductor material; a fin structure comprising the semiconductor material which extends from a bottom of the trench structure; a photodetector material which contacts the fin structure within the trench structure and comprising a material with a different lattice constant than the fin structure; a conductive material over the photodetector material; and a first contact connected to the conductive material on a side of the photodetector material.

In an aspect of the disclosure, a method comprises: forming a trench structure in a semiconductor substrate; forming at least one fin structure comprising semiconductor material extending from a bottom of the trench structure; forming a photodetector material within the trench structure and extending from the at least one fin structure; forming a first contact connecting to and on a first side of the photodetector material; and forming a second contact connecting to the semiconductor substrate on a second side of the photodetector material.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a photodetector in accordance with aspects of the present disclosure.

FIG. 2 shows a photodetector in accordance with aspects of the present disclosure.

FIG. 3 shows a photodetector in accordance with aspects of the present disclosure.

FIG. 4 shows a photodetector in accordance with aspects of the present disclosure.

FIG. 5 shows a photodetector in accordance with aspects of the present disclosure.

FIG. 6 shows a photodetector in accordance with aspects of the present disclosure.

FIG. 7 shows a photodetector in accordance with aspects of the present disclosure.

FIG. 8 shows a photodetector in accordance with aspects of the present disclosure.

FIG. 9 shows a photodetector in accordance with aspects of the present disclosure.

FIGS. 10A-10G show processing steps for the fabrication of the photodetector 10 of FIG. 1.

### DETAILED DESCRIPTION

The present disclosure relates to semiconductor structures and, more particularly, to photodetectors and methods of manufacture. More specifically, the photodetectors comprise semiconductor material seeded from a fin structure (e.g., protrusion) provided at a bottom of a trench structure formed in a semiconductor substrate. Advantageously, by forming the photodetectors on a fin structure they may have multiple degrees of freedom during the growth process thereby exhibiting lower defects and lower dark current.

In more specific embodiments, the photodetectors include a semiconductor material such as Ge, GaN, InGaAs or other III-V compound semiconductor material. The semiconductor material of the photodetectors may be formed on a fin structure (e.g., epitaxially grown on one or more protrusions) in a trench formed within a semiconductor substrate, e.g., Si material. The fin structure may preferably be the same material as the semiconductor substrate. In embodiments, the photodetectors may be epitaxially grown from a seed layer formed on the fin structure, e.g., at a bottom of a trench. The fin structure and the photodetector may be surrounded by a dielectric material (e.g., oxide) lining the trench structure. By utilizing the fin structure to grow the photodetector material, the non-lattice matched epitaxy semiconductor material of the photodetector will have more dimensions to expand compared to planar epitaxial growth processes on semiconductor substrates. This results in less defects, eliminates a leakage pathway and lowers dark current, thereby making the photodetector more efficient.

The photodetectors of the present disclosure can be manufactured in a number of ways using a number of different tools. In general, though, the methodologies and tools are used to form structures with dimensions in the micrometer and nanometer scale. The methodologies, i.e., technologies, employed to manufacture the photodetectors of the present disclosure have been adopted from integrated circuit (IC) technology. For example, the structures are built on wafers and are realized in films of material patterned by photolithographic processes on the top of a wafer. In particular, the fabrication of the photodetectors uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

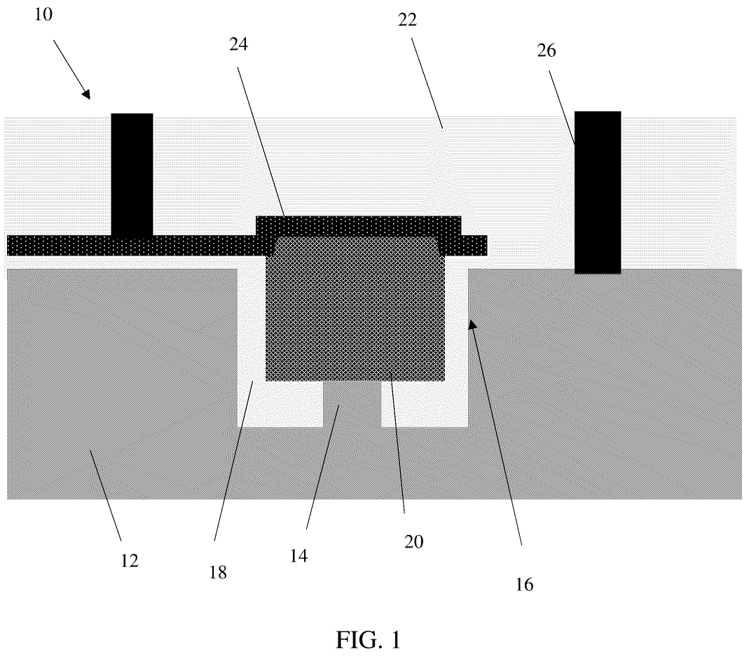

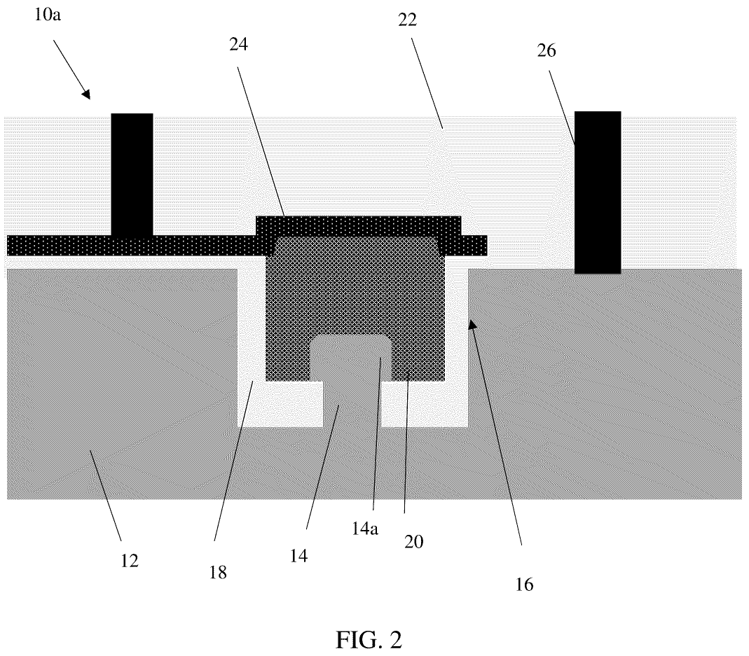

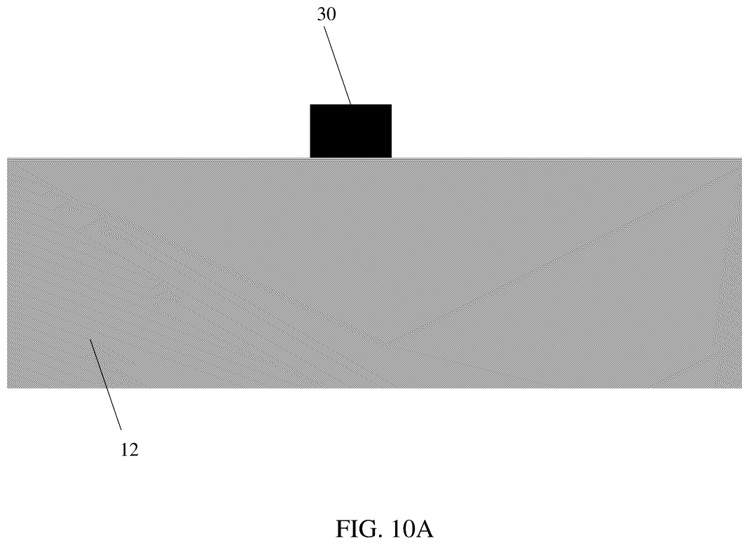

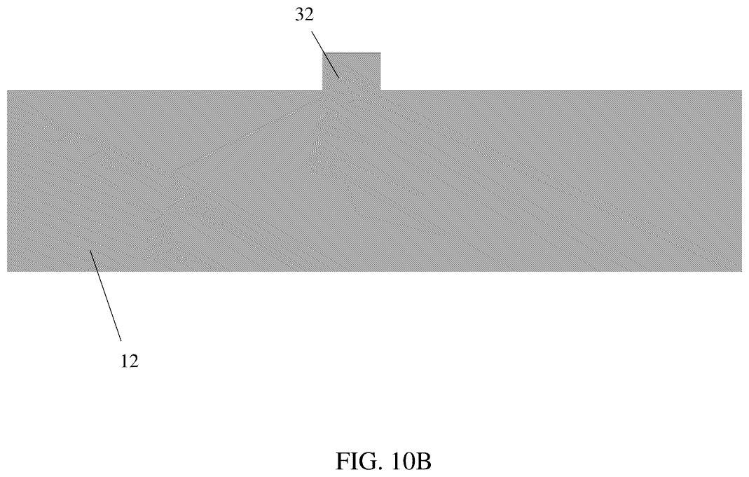

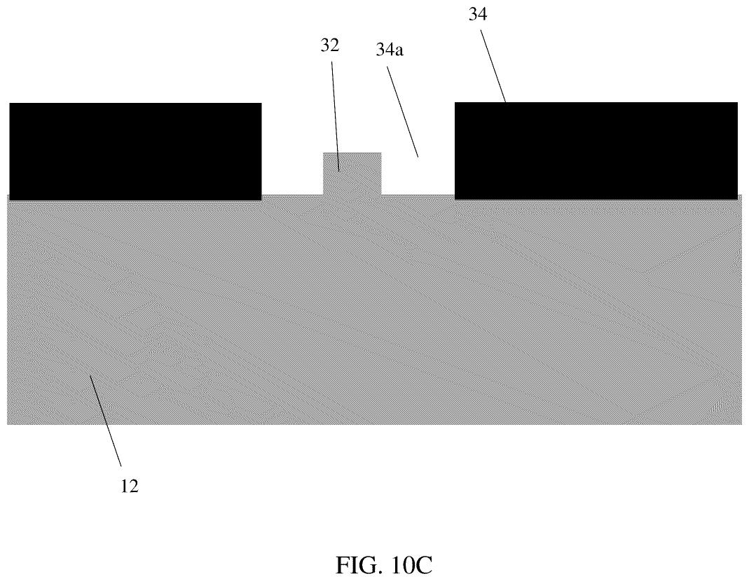

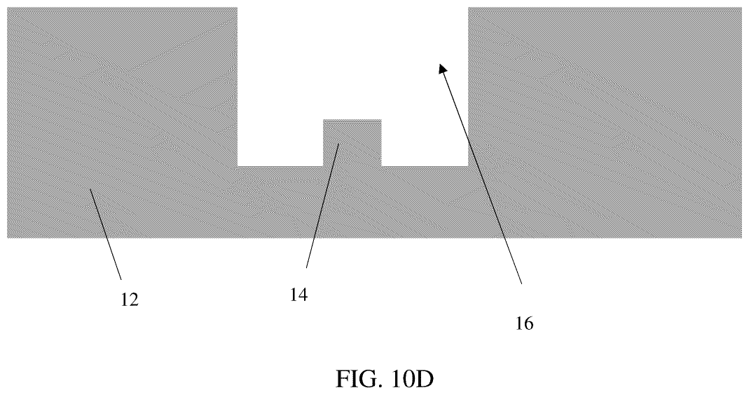

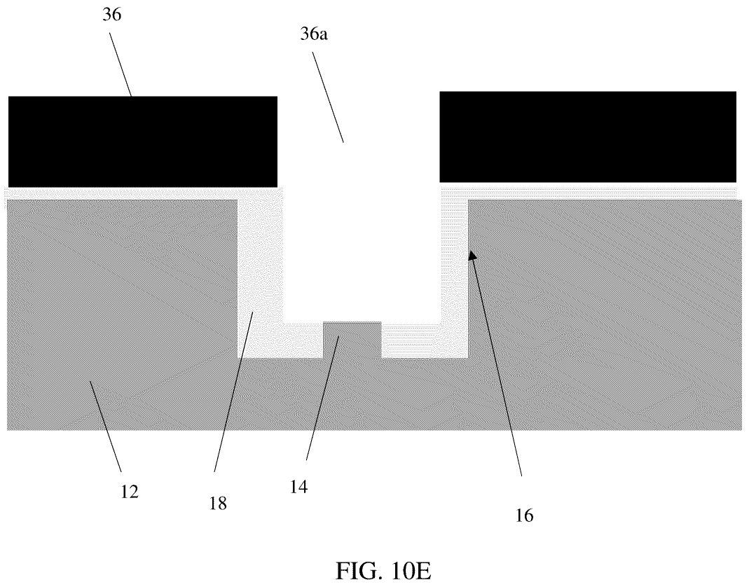

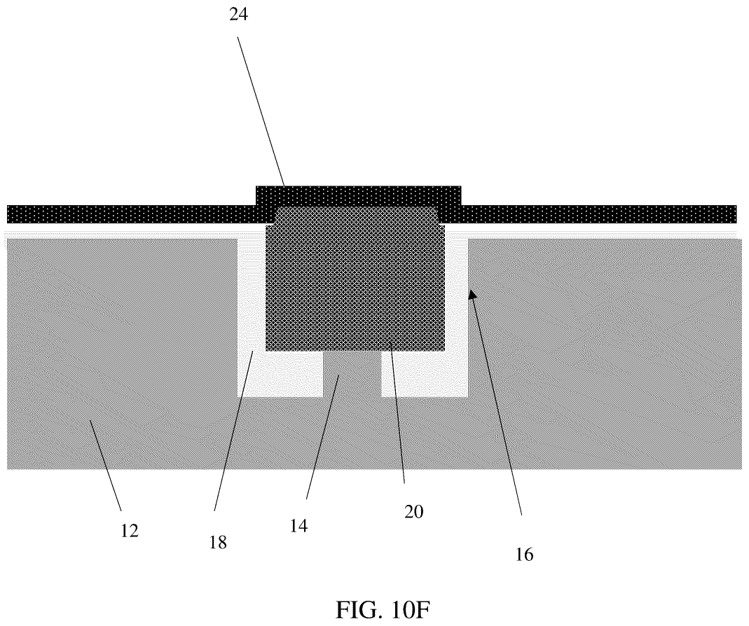

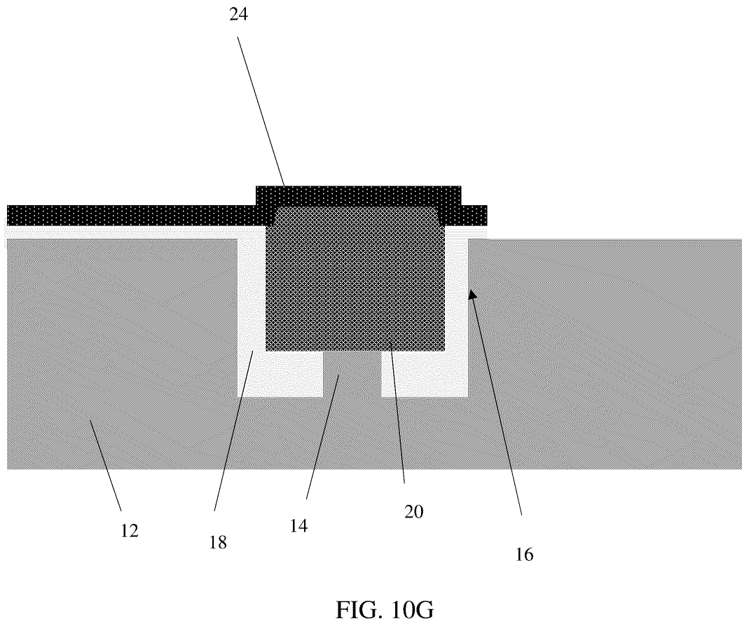

FIG. 1 shows a photodetector in accordance with aspects of the present disclosure. More specifically, the photodetector 10 of FIG. 1 includes a substrate material 12 comprising semiconductor material. In embodiments, the semiconductor material may be single crystalline Si material; although other semiconductor materials are contemplated herein as should be understood by those of skill in the art. A protrusion (e.g., fin structure) 14 may be provided within a trench structure 16 formed within the substrate material 12. The trench structure 16 and the fin structure 14 may be formed using conventional lithography and etching processes as described in more detail with respect to FIGS. 10A-10D. In embodiments, the fin structure 14 may be rectangular in shape, protruding from a bottom of the trench structure 16; although the fin structure 14 may be other shapes and configurations as described with respect to FIGS. 2-9, for example.

Still referring to FIG. 1, photodetector material 20 may be formed on the fin structure 14 within the trench structure 16. In embodiments, the photodetector material 20 may be different material than the substrate material 14. For example, the photodetector material 20 may be Ge, GaN, InGaAs or other III-V semiconductor material. As described in more detail with respect to FIG. 10F, the photodetector material 20 may be epitaxially grown from the fin structure 14. In this embodiment, the photodetector material 20 may extend above the upper surface of the substrate material 12; although other configurations are also contemplated herein as shown in FIGS. 2-9. As in each of the embodiments, the epitaxial growth process starting from the fin structure 14 provides additional degrees of freedom for the photodetector material 20 to grow leading to lowered defectivity compared to conventional growth processes on a planar surface.

The remaining portions of the trench structure 16 may be filled with a dielectric material 18, e.g., silicon oxide. The dielectric material 18 may also be formed on the surface of the substrate material 12. A layer of dielectric material 22 may be formed over the dielectric material 18 and substrate material 12. A conductive material 24 may contact the photodetector material 20, which extends to a side thereof. The conductive material 24 may be semiconductor material, e.g., polysilicon material. The dielectric material 22 may be formed over the conductive material 24. The dielectric material 22 may be SiO₂ or other interlevel dielectric materials such as layers of nitride and oxide deposited by a blanket deposition process such as a chemical vapor deposition (CVD) process.

Contacts 26 may be formed to exposed portions of the substrate material 12 and the conductive material 24. In embodiments, the contacts 26 may be formed on sides of the photodetector material 20 so as to not interfere with light absorption by the photodetector material 20. The contacts 26 may be tungsten or aluminum, as examples. The contacts 26 may be formed by conventional lithography, etching and deposition methods as described herein.

FIG. 2 shows a photodetector 10a in accordance with additional aspects of the present disclosure. In this embodiment, the fin structure 14 includes a protuberance shaped top portion 14a, with the photodetector material 20 surrounding the protuberance shaped top portion 14a. Accordingly, in this embodiment, the photodetector material 20 may be grown from all sides of the protuberance 14a. The remaining features of the photodetector 10a of FIG. 2 are similar to the photodetector 10 of FIG. 1.

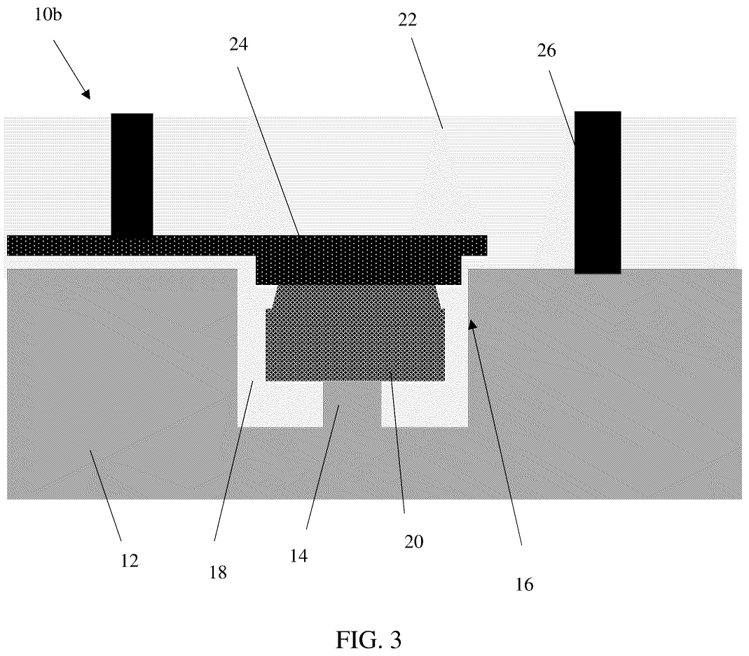

FIG. 3 shows a photodetector 10b in accordance with additional aspects of the present disclosure. In this embodiment, the photodetector material 20 has a top surface which may be recessed below an upper surface of the substrate material 12. The conductive material 24 may extend to within the trench 16 to contact the photodetector material 20. The remaining features of the photodetector 10b of FIG. 3 are similar to the photodetector 10 of FIG. 1.

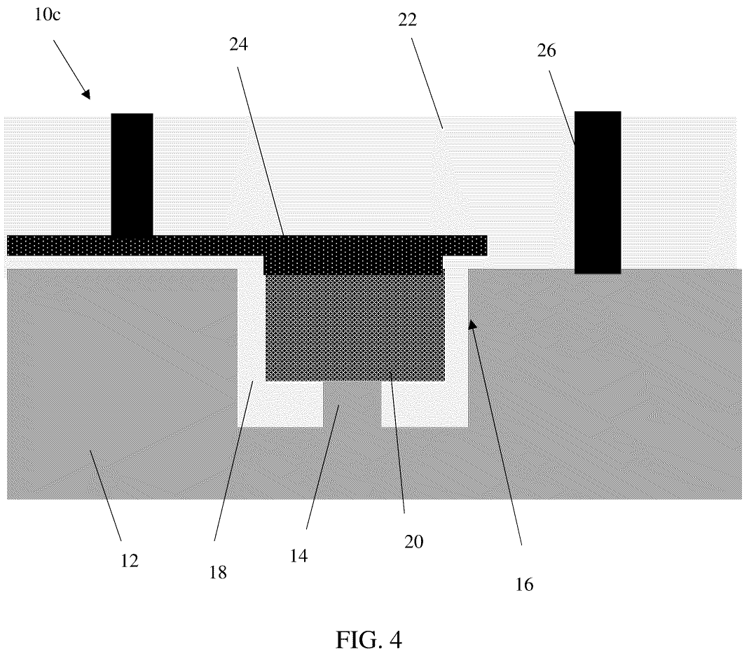

FIG. 4 shows a photodetector 10c in accordance with additional aspects of the present disclosure. In this embodiment, the photodetector material 20 has a top surface which may be planar with an upper surface of the substrate material 12. The conductive material 24 may contact the photodetector material 20 above the trench 16 and upper surface of the substrate material 12. The remaining features of the photodetector 10c of FIG. 4 are similar to the photodetector 10 of FIG. 1.

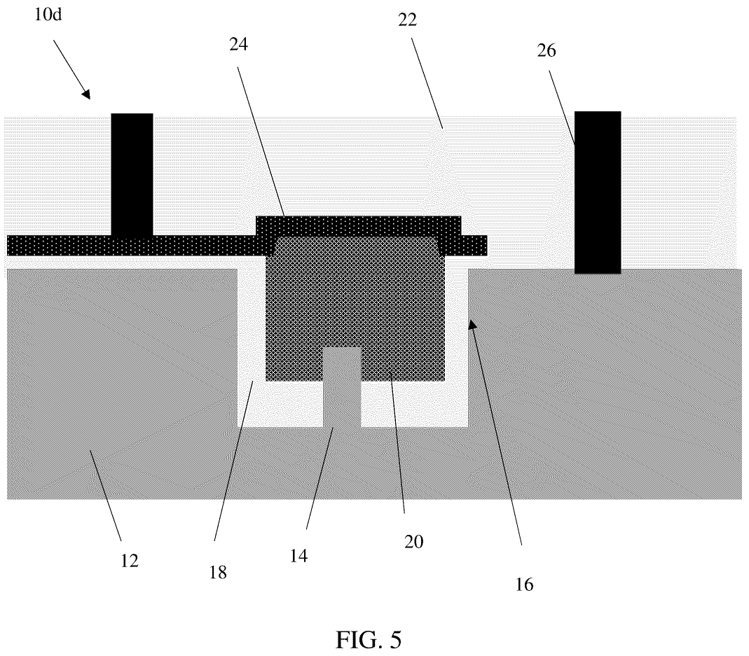

FIG. 5 shows a photodetector 10d in accordance with additional aspects of the present disclosure. In this embodiment, the photodetector material 20 may surround an upper portion of the fin structure 14. Accordingly, in this embodiment, the photodetector material 20 may be grown from all sides of the fin structure 14. Additionally, in this embodiment, the fin structure 14 does not have a protuberance as described in FIG. 2. The remaining features of the photodetector 10d of FIG. 4 are similar to the photodetector 10 of FIG. 1.

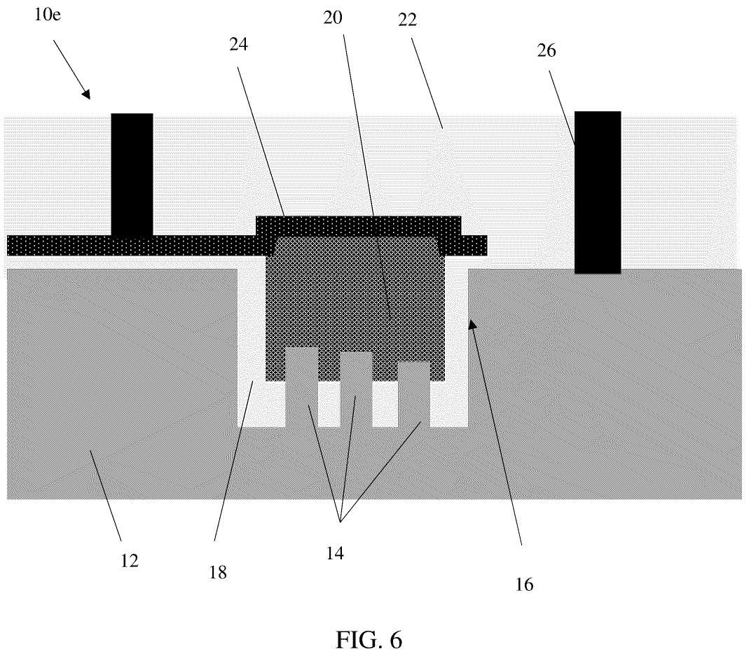

FIG. 6 shows a photodetector 10e in accordance with additional aspects of the present disclosure. In this embodiment, the photodetector material 20 may surround an upper portion of multiple fin structures 14 within the trench structure 16. Accordingly, in this embodiment, the photodetector material 20 may be grown from all sides of multiple fin structures 14. In embodiments, a larger fin structure 14 or multiple fin structures 14 may be used to advance a faster epitaxial growth process. The remaining features of the photodetector 10e of FIG. 5 are similar to the photodetector 10 of FIG. 1.

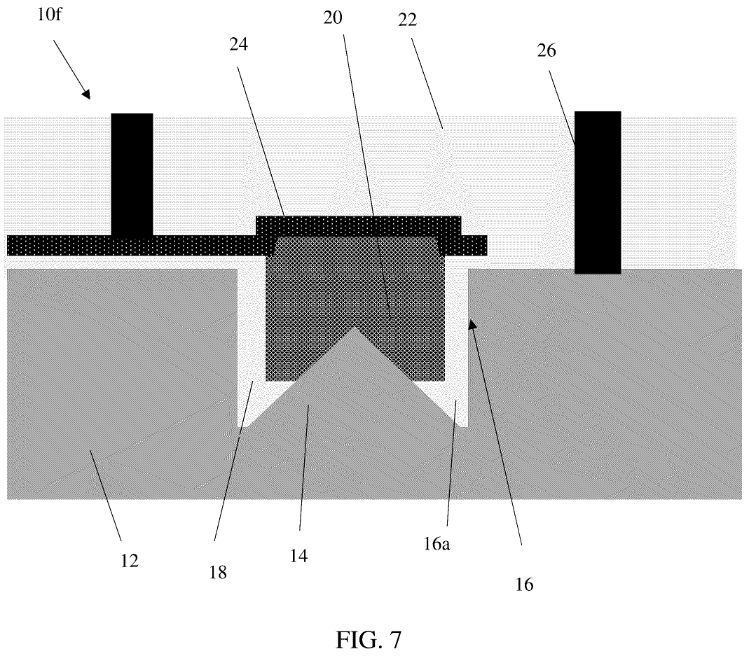

FIG. 7 shows a photodetector 10f in accordance with additional aspects of the present disclosure. In this embodiment, the fin structure 14 is tapered, e.g., V shaped, resulting in V-shaped grooves 16a in the trench structure 16. The V-shaped grooves 16a of the trench structure 16 may be filled with the dielectric material 18, e.g., oxide. The photodetector material 20 may surround an upper portion of the tapered fin structure 14. Accordingly, in this embodiment, the photodetector material 20 may be grown from multiple sides of the fin structure 14. The remaining features of the photodetector 10f of FIG. 7 are similar to the photodetector 10 of FIG. 1.

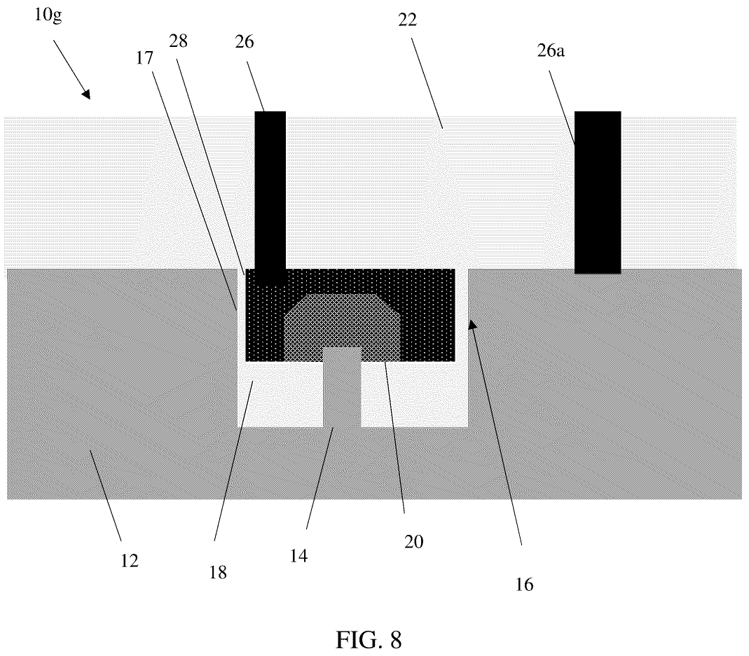

FIG. 8 shows a photodetector 10g in accordance with additional aspects of the present disclosure. In this embodiment, the trench structure 16 is partially filled with dielectric material 18 (e.g., oxide) below the photodetector material 20 and below a top surface of the fin structure 14. A semiconductor material 28, e.g., polysilicon material, surrounds the photodetector material 20 and fills remaining portions of the trench structure 16, with insulator sidewalls 17, e.g., oxide, on the sidewall of the trench structure 16 between the semiconductor material 28 and the semiconductor substrate 12.

A contact 26 is provided to the polysilicon material 28 on a side of the photodetector material 20, and another contact 26a is provided to the substrate material 12. In addition, the photodetector material 20 may include tapered corners and can be grown from all sides of the fin structure 14. As with each of the embodiments, the photodetector material 20 may be planar, above or below the upper surface of the substrate material 12.

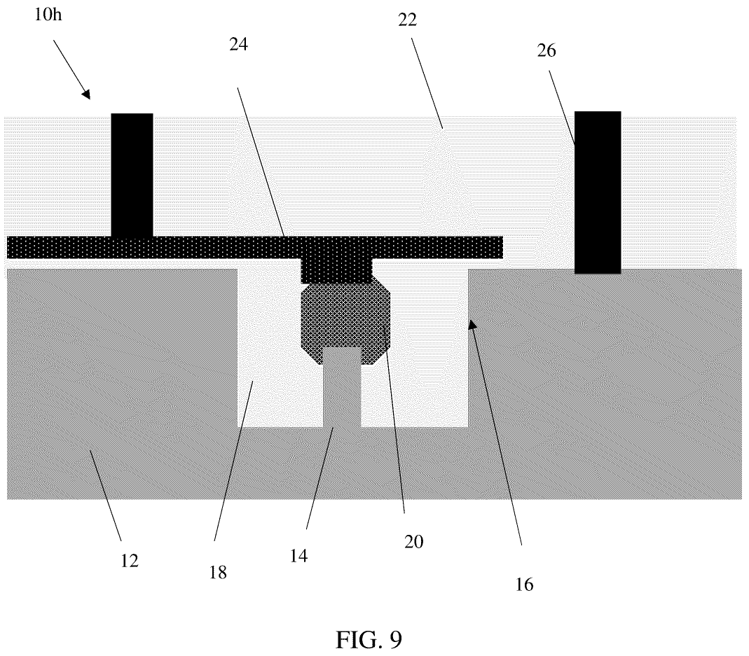

FIG. 9 shows a photodetector 10h in accordance with additional aspects of the present disclosure. In this embodiment, the photodetector material 20 may include tapered corners and can be grown from all sides of fin structure 14. Also, the trench structure 16 is completely filled with oxide material 18. The remaining features of the photodetector 10h of FIG. 9 are similar to the photodetector 10 of FIG. 1, including the conductive material 24 contacting the photodetector material 20 and configuration of the contacts 26.

FIGS. 10A-10G show processing steps for the fabrication of the photodetector 10 of FIG. 1. It should be understood by those of skill in the art that similar processing steps may be used for the fabrication of each of the embodiments provided herein, with use of different mask shapes for different fin configurations. In addition, the epitaxial growth process of the photodetector material 20 may be adjusted depending on whether the photodetector material 20 is above, planar with or below a surface of the substrate material 12 as shown in the various embodiments.

FIG. 10A shows a patterned photoresist 30 on the substrate material 12. The photoresist 30 may be patterned by conventional lithography processes, e.g., the photoresist 30 is formed on the substrate material 12 and is exposed to energy (light) and developed to form a pattern. The pattern will be similar in width to that of the fin structure.

In FIG. 10B, the substrate material 12 is patterned to form a mesa structure 32, which has a width or diameter similar to that of the fin structure 14. The mesa structure 32 may be formed by conventional etching processes, e.g., reactive ion etching (RIE) using the patterned photoresist 30. Following the formation of the mesa structure 32, the patterned photoresist 30 may be stripped using conventional oxygen ashing processes or other known stripants.

FIG. 10C shows a patterned photoresist 34 on the substrate material 12. The photoresist 34 will have an opening 34a surrounding the mesa structure 32 and which matches the dimensions (e.g., diameter or width) of the trench structure 16. The photoresist 34 may be patterned by conventional lithography processes, e.g., the photoresist 34 is formed over the substrate material 12 and is exposed to energy (light) and developed to form the pattern (e.g., opening 34a).

In FIG. 10D, the substrate material 12 may be patterned to form the trench structure 16 and the fin structure 14. As should be understood by those of skill in the art, the fin structure 14 forms due to the initial formation of the mesa structure 32. That is, as the trench structure 16 is etched into the substrate material 12 with the existing topography of the mesa structure, this topography will be transferred to the bottom of the trench structure 16 forming the fin structure 14. The patterned photoresist 34 may be stripped using conventional oxygen ashing processes or other known stripants.

In FIG. 10E, the trench structure 16 is filled with dielectric material 18. In embodiments, the dielectric material 18 may be deposited by a CVD process. In this way, the dielectric material 18 may be deposited over the fin structure 14 and an upper surface of the substrate material 12. The dielectric material 18 may be planarized using a conventional chemical mechanical polishing (CMP) process.

A patterned photoresist 36 may be formed on the dielectric material 18. The patterned photoresist 36 may include a pattern 36a (e.g., opening) aligned with the dielectric material 18 within the trench structure 16. In more specific embodiments, the pattern 36a may be slightly smaller than the dimensions of the dielectric material 18 within the trench structure 16. In this configuration, the dielectric material 18 may be subjected to an etching process, e.g., RIE, which results in removal of the dielectric material 18 to expose the fin structure 14, while still remaining on sidewalls of the trench structure 16.

It should be recognized that for photodetector 10g of FIG. 8, the pattern 36a of the photoresist 36 may be a same dimension as the trench structure 16 such that the dielectric material 18 will be removed from the sidewalls of the trench structure 16 during an etching process. In any of the embodiments, though, the dielectric material 18 may be removed to expose portions of the fin structure 14. For example, in the etching process the dielectric material 18 may be removed to expose a top portion of the fin structure 14 or multiple surfaces of the fin structure 14, depending on the particular embodiment.

In FIG. 10F, the patterned photoresist 36 may be stripped using conventional oxygen ashing processes or other known stripants. The photodetector material 20 may be epitaxially grown on the exposed surface(s) of the fin structure 14. In this way, the photodetector material 20 may grow unrestrained in different directions thereby eliminating any defects due to a lattice mismatch between the photodetector material 20 and the substrate material 12. Depending on the particular embodiment, the photodetector material 20 may be grown to above the surface of the substrate material 12, planar with the surface of the substrate material 12 or below (e.g., recessed) the surface of the substrate material 12. The photodetector material 20 may be Ge, GaN, InGaAs or other III-V compound semiconductor material. The conductive material 24, e.g., polysilicon material, may be deposited over the dielectric material 18 and on the exposed surfaces of the photodetector material 20.

In optional embodiments, prior to the epitaxial growth of the photodetector material 20, it is contemplated to grow a selective Si buffer layer on the fin structure 14. This Si buffer layer, e.g., protuberance 14a, may be used to improve fin shape, size and/or defectivity as shown in FIG. 2, for example. In addition, as an optional processing step, it is also contemplated to subject the photodetector material 20 to an anneal, e.g., approximately >700° C. in H₂ for about >1 min. This process may be used to reflow and improve the quality of Ge material after deposition.

FIG. 10G shows the patterning of the conductive material 24, e.g., polysilicon material and the dielectric material 18. More specifically, the conductive material 24, e.g., polysilicon material, and the dielectric material 18 may be patterned on a side of the photodetector material 20 (or trench 16) to expose a portion of the substrate material 12. In embodiments, the patterning may be performed using a patterned photoresist as already described herein.

Referring back to FIG. 1, a dielectric material 20 may be deposited on the conductive material 24, e.g., polysilicon material, and the substrate material 12. The dielectric material 20 may be deposited by conventional CVD processes and may include any combination of oxide and nitride layers. The dielectric material 20 may be patterned to form vias or trenches to expose the conductive material 24, e.g., polysilicon material, and the substrate material 12 on opposing sides of the trench structure 16 or photodetector material 20.

Prior to contact formation, the exposed conductive material 24 and the substrate material 12 may undergo a silicide process. As should be understood by those of skill in the art, the silicide process begins with deposition of a thin transition metal layer, e.g., nickel, cobalt or titanium, over the exposed conductive material 24 and the substrate material 12. After deposition of the material, the structure is heated allowing the transition metal to react with exposed conductive material 24 and the substrate material 12 forming a low-resistance transition metal silicide. Following the reaction, any remaining transition metal is removed by chemical etching, leaving silicide contacts. Contacts 26 may be formed over the metal silicide contacts. The contacts 26 may comprise tungsten deposited using a CVD process, followed by a planarization process, e.g., CMP process.

The photodetectors can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multichip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a trench structure in a semiconductor substrate;
at least one fin structure comprising semiconductor material which extends from a bottom of the trench structure;
a photodetector material within the trench structure and extends from the at least one fin structure;
a first contact connected to and on a first side of the photodetector material; and
a second contact connected to the semiconductor substrate on a second side of the photodetector material.

2. The structure of claim 1, wherein the at least one fin structure and the semiconductor substrate comprise a same semiconductor material and the photodetector material comprises a semiconductor material different than the fin structure and the semiconductor substrate.

3. The structure of claim 1, wherein the photodetector material comprises a lattice constant different than the at least one fin structure and the semiconductor substrate.

4. The structure of claim 3, wherein the photodetector material comprises one of Ge, GaN, InGaAs and another III-V compound semiconductor material.

5. The structure of claim 1, wherein the photodetector material extends above an upper surface of the semiconductor substrate.

6. The structure of claim 1, wherein the photodetector material is planar with an upper surface of the semiconductor substrate.

7. The structure of claim 1, wherein the photodetector material is recessed below an upper surface of the semiconductor substrate.

8. The structure of claim 1, wherein the fin structure includes a protuberance, and the photodetector material surrounds the protuberance.

9. The structure of claim 1, wherein the at least one fin structure comprises a tapered shape with V-shaped grooves on each side thereof which comprise the trench structure.

10. The structure of claim 1, further comprising dielectric material within the trench structure which surrounds the photodetector material and the at least one fin structure.

11. The structure of claim 1, further comprising dielectric material which fills a bottom portion of the trench structure below the photodetector material, semiconductor material in a remaining portion of the trench structure and which surrounds the photodetector material, and the first contact contacts to the semiconductor material surrounds the photodetector material.

12. A structure comprising:
a trench structure in a semiconductor material;
a fin structure comprising the semiconductor material which extends from a bottom of the trench structure;
a photodetector material which contacts the fin structure within the trench structure and comprising a material with a different lattice constant than the fin structure;
a conductive material over the photodetector material; and
a first contact connected to the conductive material on a side of the photodetector material.

13. The structure of claim 12, wherein the fin structure and the semiconductor substrate comprise a Si material and the photodetector material comprises one of Ge, GaN, InGaAs and another III-V compound semiconductor material.

14. The structure of claim 12, wherein the photodetector material is one of extends above an upper surface of the semiconductor material, is planar with an upper surface of the semiconductor material and is recessed below an upper surface of the semiconductor material.

15. The structure of claim 12, wherein the fin structure includes a protuberance, and the photodetector material surrounds the protuberance.

16. The structure of claim 12, further comprising multiple fin structures which are surrounded by dielectric material and the photodetector material.

17. The structure of claim 12, wherein the fin structure comprises a tapered shape with V-shaped grooves on each side and the V-shaped grooves are filled with a dielectric material.

18. The structure of claim 12, further comprising dielectric material within the trench structure, which surrounds the photodetector material and the fin structure.

19. The structure of claim 12, further comprising the trench structure partially filled with dielectric material below the photodetector material, semiconductor material in a remaining portion of the trench structure which surrounds the photodetector material, and the first contact contacts to the semiconductor material which surrounds the photodetector material.

20. A method comprising:
forming a trench structure in a semiconductor substrate;
forming at least one fin structure comprising semiconductor material extending from a bottom of the trench structure;
forming a photodetector material within the trench structure and extending from the at least one fin structure;
forming a first contact connecting to and on a first side of the photodetector material; and
forming a second contact connecting to the semiconductor substrate on a second side of the photodetector material.
